(19) United States
(12) Patent Application Publication
(10) Pub. No.: US 2009/0151785 A1
(43) Pub. Date: Jun. 18, 2009

(54) SOLAR CELL AND ITS SPECTRUM CONVERTER

(76) Inventors: Soshchin Naum, Changhua City (TW); Wei-Hung Lo, Taipei City (TW); Chi-Ruei Tsai, Taipei City (TW)

Correspondence Address: The Weintraub Group, P.L.C., 28580 Orchard Lake Road, Suite 140, Farmington Hills, MI, 48334, US

(21) Appl. No.: 12/241,493

(22) Filed: Sep. 30, 2008

(30) Foreign Application Priority Data
Dec. 12, 2007 (TW) 096147537

(51) Int. Cl. H01L 31/00

(52) U.S. Cl. 136/257

(57) ABSTRACT

A solar cell is disclosed to include a single crystal silicon chip, an electrode system, a glass plate cover, a polymer film set between the single crystal silicon chip and the glass plate cover, and a spectrum converter containing an inorganic phosphor, which absorbs radiation in purple, blue and green light of the Sun's solar radiation and converts the absorption into a photoluminescent light in yellow, orange-yellow and infrared area in the electromagnetic spectrum. The architecture characteristic of the solar cell increases the efficiency by about 20%.

### BACKGROUND OF THE INVENTION

1. Field of the Invention

The present invention relates to energy technology and more particularly, to a solar cell that, unlike the natural resources of petroleum, natural gas and coal, enhances the photo conversion efficiency of the solar cell through a spectrum converter.

2. Description of the Related Art

Solar cell, more specifically, silicon-based solar cell is a self-provided energy intensively used in modern technology products such as mobile communication apparatus, microelectromechanical devices and lighting fixtures. For astro navigation, solar cell is the only applicable energy source. Solar cell technology is a special field having concern with the research of solar cell technology.

FIG. 1 is a schematic drawing showing the structure of a regular single crystal silicon solar cell. As illustrated, the single crystal silicon solar cell is a device comprising a housing 10, a single crystal silicon 20 accommodated in the housing 10, and a p-n junction 30 on the surface of the single crystal silicon 20. The aforesaid solar cell generates energy when radiated by light. The aforesaid solar cell further comprises an electrode system 50, a conversion layer 60, and a glass 70 covering the conversion layer 60. This p-n junction 30 is a thin boundary. When sunlight radiates the single crystal silicon 20, the p-n junction 30 can divide from the space the electrons and the electron hole in the single crystal silicon 20. The silicate glass 70 protects the solar cell against the effect of the atmosphere. The single crystal silicon 20 is connected with the conversion layer 60. The conversion layer 60 is prepared from ethyl acetoacetic polymers. The solar cell that is based on the single crystal silicon 20 and covered with the silicate glass 70 is affixed to the inside of the housing 10. The housing 10 also houses other silicon cells.

Certain parameters may be applied to explain the characteristics of the solar cell. These parameters include cell voltage V (Voltage), cell current J (Ampere), cell maximum supply power W (Watt), and the most important actual efficiency ζ (%).

According to measurements, when the light of the sun is radiating the surface of the earth, the radiation energy power on the surface of the earth is 0.1 W/cm² or 1000 W/m². Due to many different factors, a certain fraction of the radiation of the sun is converted into effective power. This conversion has concern with the purity of the single crystal silicon chip and the transition rate of the electric energy carrier. According to many different theories of computation, this fraction in one single crystal silicon chip does not exceed by 24% (see K. Chopra 1986, Thin-Film Solar Cell, Word Publication Corp.). However, no any physical single crystal silicon-based solar cells achieve this theoretical extreme value. The efficiency of industrial solar cells provided by some world famous companies, for example, “Suntech”, is about 14˜16% (please go to www.suntech.com for the related data). Because of low efficiency in converting solar energy into power, the cost of the use of conventional solar cells and solar cell sets is high. How to raise the efficiency of a single crystal silicon-based solar cell is an important subject in the development of green energy technology. The invention pertains to the study of this subject, and provides a measure to improve the spectrum conversion efficiency of solar cell.

FIG. 2 illustrates the radiation of solar spectrum at 38 degrees North Latitude at mid-day. In earth, at 38˜40 degrees North Latitude at mid-day, a professional spectroradiometer was used to draw the curve. This curve shows the characteristic that a spectrum radiation maximum value is clearly seen at 470 nm. Under this condition, the total deviation of the curve is ±2˜5%. It depends upon the optical status of the atmosphere of the earth and physical drop in the spectrum, such as existence of O₂, CO, CO₂, H₂O in the atmosphere in the 900-nanometer range.

FIG. 3 illustrates the photosensitive spectrum curve of a standard single crystal silicon chip under the radiation of the light of the sun. In this curve, the abscissa indicates the wavelength of activated light (nm), the ordinate indicates the electric power (mW/cm²). By means of comparing the curves shown in FIGS. 2 and 3, a significant difference is shown. Thus, if the maximum value of the radiation of the sun is at λ=470 nm with half-wave width Δ≧400 nm, thus, the maximum value of the photosensitive spectrum of the single-chip solar cell is in the range of λ=960˜1020 nm, and the half-wave width increased by Δ=300 nm. We found that the difference between the location of the maximum value of the photosensitive spectrum of the solar cell and the location of the maximum value of the radiation of the light of the sun over 600 nm is the major reason why the efficiency of the solar cell is lower than the theoretical value. By means of rating curve continued multiplication (multiply the value of FIG. 2 by the value of FIG. 3), i.e., convert every maximum value to 100%, a new spectrum curve is obtained (see FIG. 4). This new curve is the optimum spectrum radiation curve. The spectrum maximum value is at λ=560˜800 nm. Apparently, this maximum value is not in conformity with the maximum value of the radiation of the light of the sun or the photosensitive maximum value of a single crystal silicon chip.

The concept of the change of the maximum value of the radiation spectrum projected onto a single crystal silicon-based solar cell was developed in the 70˜80's of the last century (see the related data at hptt//www.suntech-power.com). According to this concept, there is a spectrum conversion layer in the optical radiation path of the sun, such as ruby single crystal-based Al₂O₃.Cr⁺³. In this spectrum conversion layer, the short wave of the solar radiation λ=320˜420 nm activates Cr⁺³ in ruby to emit light strongly. Thus, adding this ruby single crystal to the primary light-emitting composition to support the emission of red light causes displacement of long wave in the solar radiation. Further, because the quantum efficiency of the radiation of Al₂O₃.Cr⁺³ is as high as η≧50%, the short wave loss of the radiation of the sun is below 50%. The loss of the radiation of long wave 700˜1100 nm through the ruby single crystal does not surpass 30˜40%. According to the introduced data (see Y. J. Hovel Solar Energy, mat. 2 p. 19, 1979), increasing of “carrier collection coefficient” in a single crystal silicon-based solar cell relatively causes increasing of the efficiency of the solar cell. However, there is no any disclosure data regarding to the use of a ruby-based spectrum converter in a big scale solar cell.

U.S. Pat. No. 4,367,367 (Apr. 1, 1983) issued to Reisfeld R discloses means for concentrating solar energy on solar cells, optimizing the utilization of solar energy. This disclosure teaches the use of planar or substantially planar glass plates, doped in a suitable manner, provided with reflecting means at the lateral sides and at the lowermost glass surface, a solar cell being attached to one of the lateral sides of the glass plate. This invention is illustrated with reference to one single glass plate, advantageously doped with uranyl ions, possibly also with additional ions, for example, Yb⁺³; and furthermore with reference to solar collectors based on the use of a plurality of plates of different glasses, each of which is provided with a solar cell having a high efficiency at the wavelength at which the respective glass fluoresces. The invention utilizes this teach as the prime model.

A solar cell based on a glass plate doped with spectrum converting means subject to the aforesaid patent brings certain advantages, however it still has substantial drawbacks as follows:

1. The fabrication of the spectrum converting glass plate requires the application of complicated techniques as well as the use of professional high-temperature glass furnace and high purity reagent. Further, the cost of the spectrum converting glass plate is high, and the related precision cutting and polishing processing cost is also high.

2. The photoluminescence quantum efficiency of the spectrum converting glass plate is normally low, not higher than η=20˜40%. The non-crystal architecture of the glass plate limits the emitting of light, i.e., there is only a near-field rhythmic effect in the coordination surrounding structure around the active ions. At this time, the action force of the periodic structure in the single crystal architecture affects the action of the active ions. Lowering of the strength and quantum efficiency of the non-crystal architecture of the photoluminescence glass plate has concern with the increasing of the radiation spectrum of the activator and the width of the spectrum half wave.

3. The excitation spectrum of the photoluminescence glass plate has scattering characteristic and weak absorbing lines. People may try to eliminate this problem by means of increasing the concentration of the active ions in the volume of the spectrum converting glass plate, however the concentration quenching of the activated ions in the glass plate will occur, causing dropping of the radiation strength of the activator.

4. Because the first order activation light that is projecting onto the spectrum converting surface from different angles exists in different optical concentration, the radiation of the spectrum converter is complicated. The concentration of the ions activated by light perpendicular to the surface of the spectrum converting glass plate is the smallest. At this time, the projection of light rays that fall to the spectrum converting glass plate at an acute angle cause concentration quenching in the glass plate.

5. The photoluminescence radiation of the glass plate is subject to the temperature effect of the radiation of the light of the sun. Further, the working of the spectrum converting glass plate is unstable and, the quantum efficiency of the spectrum converting glass plate is low.

6. The spectrum converting glass plate is prepared from silicate-phosphate, having the drawbacks of high fragility and low mechanical strength.

### SUMMARY OF THE INVENTION

The present invention has been accomplished under the circumstances in view. It is the main object of the present invention to provide a solar cell and the related spectrum converter, which eliminates the known drawbacks of conventional solar cells having a light conversion glass layer. It is another object of the present invention to provide a solar cell and the related spectrum converter, which substantially increases the electric parameters of single crystal silicon-based solar cell as well solar cell set. It is still another object of the present invention to provide a solar cell and the related spectrum converter, which raises the solar cells total efficiency by about 10˜20% and has this parameter in industrial samples reach 17˜19%. It is still another object of the present invention to provide a solar cell and the related spectrum converter, which has a low manufacturing cost. It is still another object of the present invention to provide a solar cell and the related spectrum converter, which achieves high stability in fabrication of single crystal silicon-based solar cell and solar cell set.

To achieve these and other objects of the present invention, a solar cell in accordance with the present invention comprises a single crystal silicon chip, an electrode system, and a glass plate covering the single crystal silicon chip, wherein the solar cell further comprises a spectrum converter set between the single crystal silicon chip and the glass plate. The spectrum converter has contained therein an inorganic phosphor to enhance the efficiency of the solar cell. The inorganic phosphor absorbs radiation in purple, blue and green light of the Sun's solar radiation and converts the absorption into a photoluminescent light in yellow, orange-yellow and infrared area in the electromagnetic spectrum.

To achieve these and other objects of the present invention, a spectrum converter in accordance with the present invention has contained therein an inorganic phosphor to enhance the efficiency of the solar cell. The inorganic phosphor absorbs radiation in purple, blue and green light of the Sun's solar radiation and converts the absorption into a photoluminescent light in yellow, orange-yellow and infrared area in the electromagnetic spectrum.

### BRIEF DESCRIPTION OF THE DRAWINGS

FIG. 1 is a schematic drawing showing the basic architecture of a conventional photovoltaic cell.

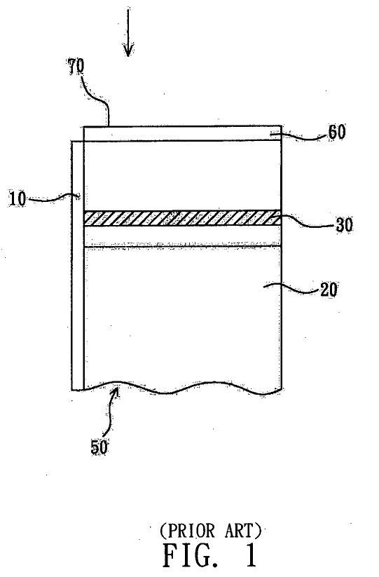

FIG. 2 illustrates the radiation of solar spectrum at 38 degrees North Latitude at mid-day in August.

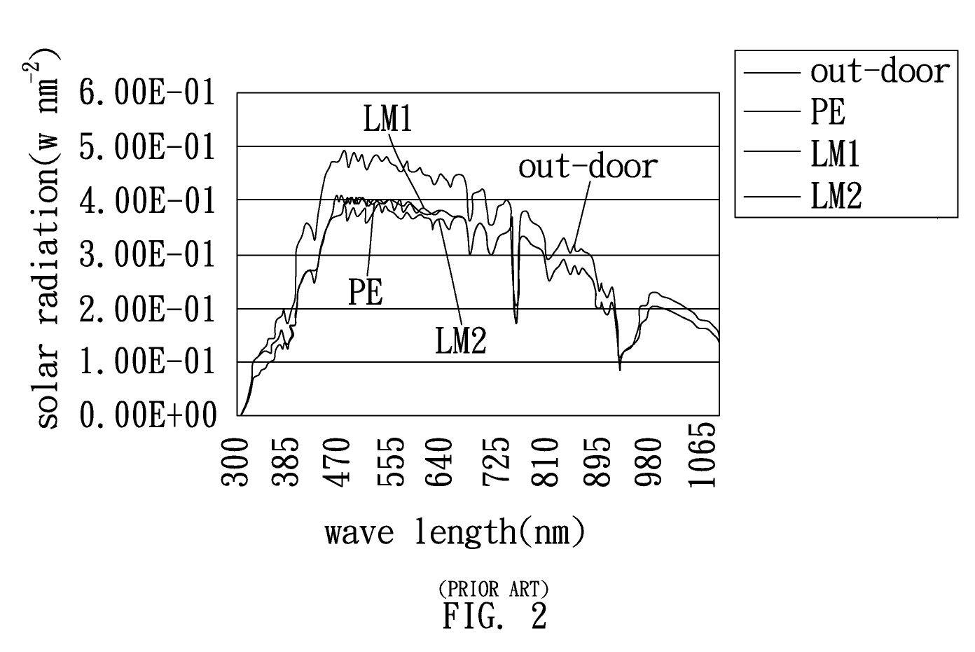

FIG. 3 is a schematic drawing, showing the photosensitive spectrum curve of a regular standard solar cell.

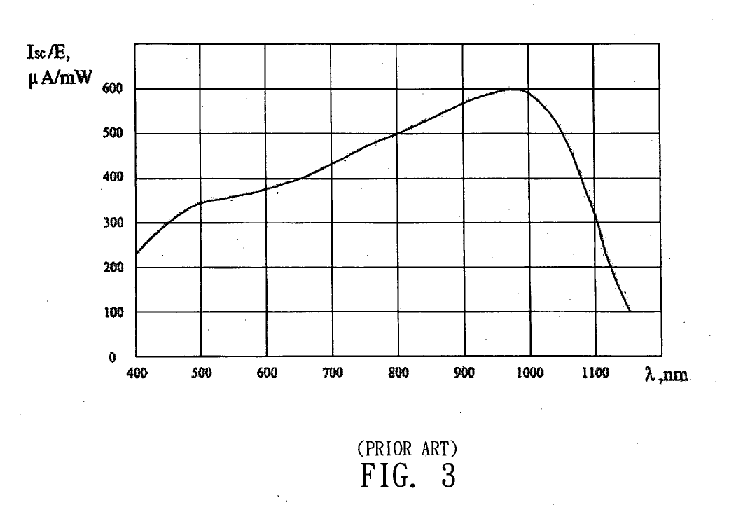

FIG. 4 is a schematic drawing, showing the optimal photosensitive spectrum curve of a regular standard solar cell.

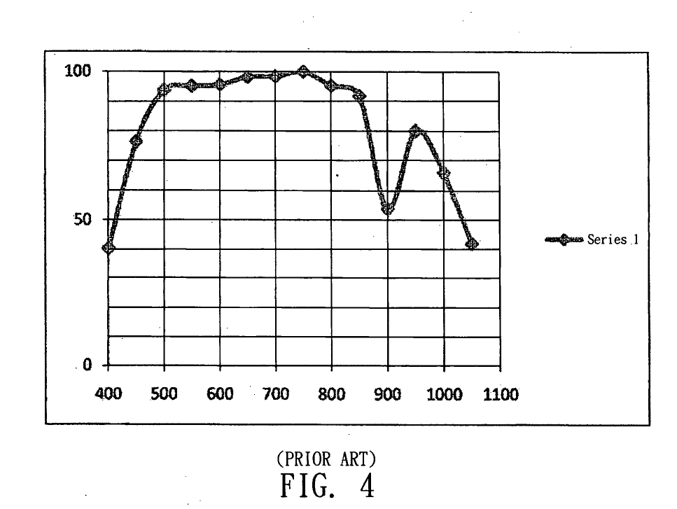

FIG. 5 is a schematic drawing, showing the structure of a silicon-based solar cell in accordance with the present invention.

FIG. 6 is a schematic drawing showing the visible part of the spectrum of the inorganic phosphur according to the present invention.

FIG. 7 is a schematic drawing showing the radiation spectrum of Nd⁺³ in the long-wave area located in the photosensitive long-wave area of the single crystal silicon chip.

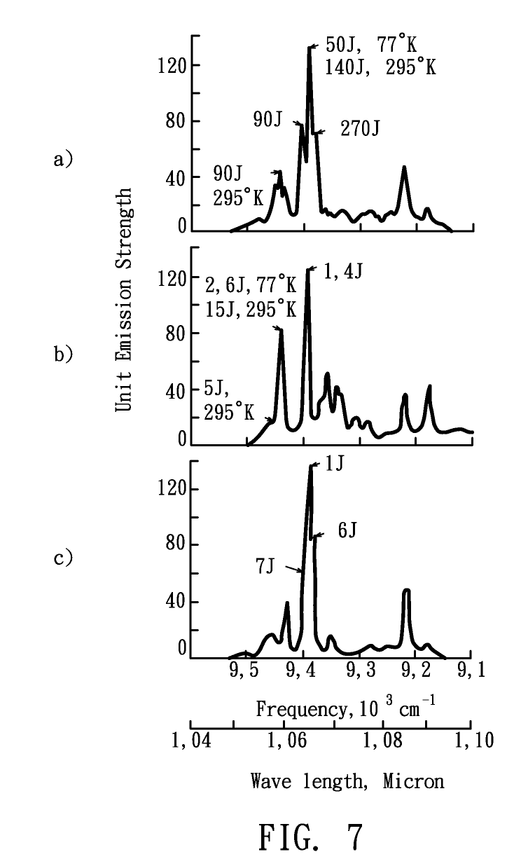

### DETAILED DESCRIPTION OF THE PREFERRED EMBODIMENT

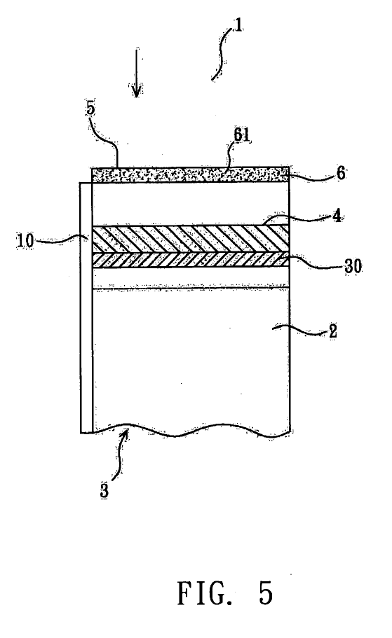

At first, the object of the present invention is to eliminate the drawbacks of the aforesaid prior art solar cell. To achieve this object, a solar cell 1 in accordance with the present invention is shown in FIG. 5, comprising a single crystal silicon chip 2, an electrode system 3, and a glass plate 5 covered on the single crystal silicon chip 2, characterized in that the solar cell 1 further comprises a spectrum converter 6 sandwiched between the single crystal silicon chip 2 and the glass plate 5. The spectrum converter 6 has filled therein an inorganic phosphor 61. The inorganic phosphor 61 absorbs purple, blue and green light of the Sun's solar radiation and converts the absorption into a photoluminescent light in yellow, orange-yellow and infrared area in the electromagnetic spectrum enhancing the efficiency of the solar cell;

Wherein, the glass plate 5 can be a silicate glass plate;

Wherein, the spectrum converter 6 is composed of an ethyl acetoacetate polymer film;

Wherein the spectrum converter 6 radiates the absorbed short wave light in the form of a multiband spectrum in which the half-wave width of one extreme surpasses 120 nm and is located on yellow-orange yellow spectrum area where the other extremes are distributed in the near infrared light 940˜1060 nm of half wave width 4˜6 nm that is in conformity with the maximum photosensitive area of the single chip silicon and within the Sun's radiation 900˜1100 nm;

Wherein the inorganic phosphor 61 has the chemical composition of Y_{3-x-y-z-p}GdₓCe_{y}LuₚNd_{z}Al₅O₁₂, in which x=0.001˜0.30, y=0.001˜0.1, z=0.0005˜0.05, p=0.0005˜0.1 and, under this condition, the active ion Ce⁺³ is within the local radiation λ=510˜720 nm and the active ion Nd⁺³ is within the local radiation λ=920˜1100 nm;

Wherein the spectrum converter 6 exists in the form of a thin film, having filled therein fine inorganic phosphor 61, and the particles of the inorganic phosphor are spaced from one another at a distance about 20 times of the average diameter of the particle size, assuring film transmittance 80˜88% and light scattering 4˜6%;

Wherein the inorganic phosphor 61 of the spectrum converter 6 has the volume concentration of 0.005˜0.025, and the light quantum efficiency of the inorganic phosphor is 0.8˜0.95 when activated by a shortwave;

Wherein the effective use of solar radiation by the spectrum converter increases the total efficiency of the solar cell by 20%.

The solar cell 1 further comprises a polymer film 4 disposed in connection with the single crystal silicon chip 2 and the spectrum converter 6 respectively, i.e., the polymer film 4 is sandwiched between the single crystal silicon chip 2 and the spectrum converter 6, wherein, the polymer film 4 is prepared from ethyl acetoacetate.

It is to be understood that the solar cell of the present preferred embodiment is based on all the known basic component parts in U.S. Pat. No. 4,367,367, including single crustal silicon chip that carries electrodes, cover glass plate, connection polymer film and spectrum converter (light conversion layer). The outstanding characteristics of the present invention are lifted in the follow Table I.

TABLE I

| | | | Solar cell |
|---|---|---|---|
| | Cell element | Known solar cells | of the invention |
| 1 | Electrode-carrying | Single crystal | Single crystal silicon |
| | photovoltaic receiver | silicon chip | chip |
| 2 | Silicate glass plate | Luminous silicate | Non-luminous silicate |
| | | glass plate | glass plate |
| 3 | Polymer film | Inactive optical | Active optical polymer |
| | | polymer | |
| 4 | Photoluminescence | Silicate-phosphate | Polymeric cover layer |
| | carrier | glass plate | based on inorganic |
| | | | phosphor distributed in |
| | | | the volume |
| 5 | Light scattering center | No light scattering | Inorganic phosphor in |
| | in spectrum converter | center | volume of polymer |
| | | | becomes the light |
| | | | scattering center |

The main feature of the present invention is at: The inorganic phosphor 61 emits light strongly in n the visible spectrum yellow-orange yellow, red and infrared area, and the photoluminescence transits the maximum value of the first order spectrum 350˜450 nm from λ=470 nm to λ₁=560˜680 nm and λ_{II}=920˜1060 nm.

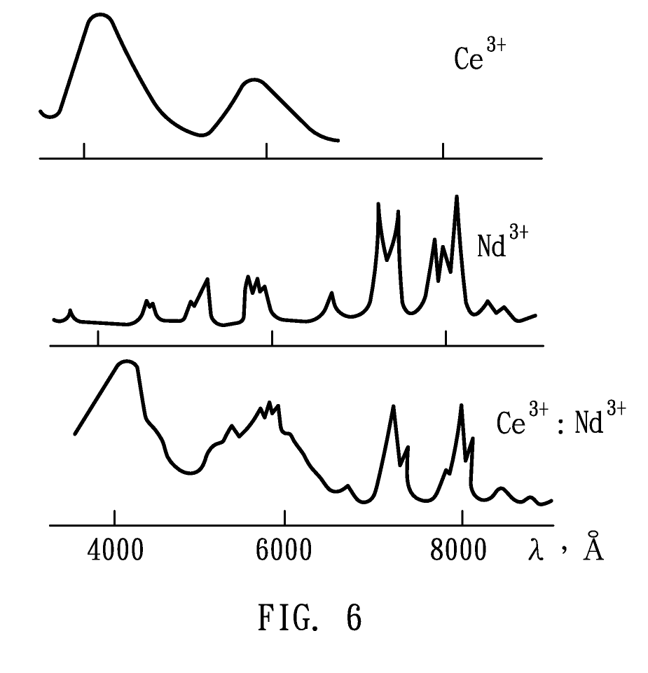

The main features of architecture of the present invention will be described hereinafter in detail. FIG. 6 illustrates the visible part of the spectrum of the inorganic phosphor 61, where the phosphor 61 is activated in blue-light blue area in the solar spectrum. Obviously, the maximum value of the radiation of this material is in the area λ=560˜570 nm within which the maximum half wave width Δ_{0.5}=120˜125 nm. The 50% maximum efficiency of the spectrum long-wave of the phosphor 61 is in λ=622 nm red electromagnetic spectrum area, and 25% maximum efficiency of the spectrum long-wave of the phosphor 61 is in 645˜650 nm, and the optimum sensitivity of the phosphor 61 relative to the solar cell is 0.95˜0.96. Even 10% extreme value of the phosphor radiation curve is located in the range of 680˜700 nm, i.e., red and dark red area of the spectrum. Within this area, the single crystal silicon chip has high photosensitivity.

If the maximum value of the first order spectrum of the radiation of the phosphor 61 of the spectrum converter 6 is determined subject to the radiation of Ce⁺³ in the oxygen-contained material, a second long-wave extreme is created to join the second active ion Nd⁺³ in the phosphor composition. Nd⁺³ Radiation are emitted excellently in the oxygen-contained substrate. It has concern with radiation transfer ⁴F_{3/2}→I_{11/2}. Obviously, the activated radiation in these spectrum lines is strongly affected by the radiation of Ce⁺³. FIG. 6 illustrates the radiation spectrum of Nd⁺³ in the long-wave area. It is apparent that this spectrum is in the photosensitive long-wave area of the single crystal silicon chip. The spectrum ratio between Ce⁺³ and Nd⁺³ determines the inorganic substrate crystal architecture and the concentration ratio of cerium and neodymium. The selection of inorganic substrate composition and architecture is significant. During the work of the present invention, we found that the optimum radiation having high quantum efficiency is mainly obtained from a garnet architecture-based cubic substrate.

This substrate has the conventional composition of Y₃Al₅O₁₂, of which the lattice cation nodes comprise big-size Ce⁺³ (ionic radius τ_{Ce}=1.06 A) and Nd⁺³ (ionic radius τ_{Nd}=1.03 A) that have the same solubility. For causing a relatively greater wavelength displacement in the long-wave area, it is necessary to add Gd⁺³ to yttrium garnet substrate. For causing a short-wave radiation displacement in the substrate, Lu⁺³ must be added. The advantage of the application in the spectrum converter 6 is characterized by: adding to the spectrum converter 6 the inorganic phosphor 61 that has the chemical composition of Y_{3-x-y-z-p}GdₓCe_{y}LuₚNd_{z}Al₅O₁₂, in which x=0.001˜0.30, y=0.001˜0.1, z=0.0005˜0.05. p=0.0005˜0.1. Under this condition, Ce⁺³ radiates in λ=510˜720 nm and, Nd⁺³ radiates in λ=920˜1100 nm. Hereinafter, we explain the reasons of selecting yttrium-gadolinium-lutetium-aluminum garnet substrate-based inorganic phosphor 61. The first reason to select yttrium-gadolinium-lutetium-aluminum garnet substrate-based inorganic phosphor 61 is to improve the luminescence efficiency. The substrate must have the minimum possible lattice parameters. Only under this condition can enhance the electric-field gradient, causing abundant recombination of radiations of Ce⁺³ and Nd⁺³. When the smaller Gd⁺³ substituted for, Y⁺³, Y₃₋ₓGdₓAl₅O₁₂ solid solution is produced, in which the lattice parameter a=12.001 A. In Y-Gd substitution in the solid solution, the concentration of the synthesized Gd ion is [Gd]=0.3 atomic fraction. When the concentration of Gd ion in the solid solution is excessively high, the radiation thus produced is not effective.

In order to reduce the Y-Gd garnet lattice parameter, the invention adopts the method of adding a small amount of lutetium to the yttrium-gadolinium garnet solid solution. At this time, we found that adding small fraction lutetium ion, i.e., [Lu⁺³]≧0.01 atomic fraction can reduce the lattice parameter to a≦12.000 A. This is an important experimental result, more particularly to the phosphor containing Ce ion and Nd ion. Adding these ions can permanently increase the lattice parameter. The dual-activator garnet of the present invention has another important factor, i.e., the selection of the concentration of the two activators Ce and Nd. As stated above, the optimum concentration should not be high. If the optimum content of Ce in the standard phosphor Y_{3-x-y}GdₓCe_{y}Al₅O₁₂ is [Ce]=0.02˜0.025 atomic fraction, this concentration in the dual-activator material can be substantially lowered without lowering the radiation quantum efficiency. On the other hand, the concentration of Nd⁺³ in Y₃Al₅O₁₂:Nd does not exceed by [Nd]=1.2%. However, the added cerium ion in these lattices involves in material cracking, and therefore the concentration of these two ions in this composition must be lowered.

In the following Table II, the physical composition of the inorganic phosphor 61 for the spectrum converter 6 of the present invention is introduced.

TABLE II

| | | Spectrum | |
|---|---|---|---|
| | | maximum | Quantum |
| No. | Inorganic phosphor composition | value nm | efficiency |
| 1 | Y_{2.9}Gd_{0.08}Ce_{0.005}Nd_{0.005}Lu_{0.01}Al₅O₁₂ | 560, 1060 | 0.86 |
| 2 | Y_{2.8}Gd_{0.16}Ce_{0.01}Nd_{0.005}Lu_{0.025}Al₅O₁₂ | 562, 1062 | 0.89 |
| 3 | Y_{2.75}Gd_{0.21}Ce_{0.01}Nd_{0.005}Lu_{0.025}Al₅O₁₂ | 566, 1062 | 0.90 |
| 4 | Y_{2.75}Gd_{0.20}Ce_{0.01}Nd_{0.005}Lu_{0.035}Al₅O₁₂ | 563, 1062 | 0.90 |
| 5 | Y_{2.75}Gd_{0.20}Ce_{0.02}Nd_{0.005}Lu_{0.025}Al₅O₁₂ | 564, 1062 | 0.85 |
| 6 | Y_{2.75}Gd_{0.20}Ce_{0.02}Nd_{0.01}Lu_{0.02}Al₅O₁₂ | 564, 1062 | 0.84 |
| 7 | Y_{2.75}Gd_{0.021}Ce_{0.02}Nd_{0.005}Lu_{0.015}Al₅O₁₂ | 565, 1062 | 0.82 |
| 8 | Y_{2.75}Gd_{0.020}Ce_{0.02}Nd_{0.02}Lu_{0.01}Al₅O₁₂ | 566, 1064 | 0.80 |
| 9 | Y_{2.75}Gd_{0.22}Ce_{0.03}Al₅O₁₂ | 560 | 0.94 |

Obviously, adding a second active ion of neodynium to the garnet phosphor will lower the light quantum efficiency when activated by blue light. However, in the visible and UV area of the spectrum, the color and quantum amount of the phosphor of the present invention show a high quantum efficiency value. The main characteristic of the composition of the phosphor of the present invention, i.e., the location of the maximum value in the phosphor that changes the maximum value of the long-wave and short-wave radiations will be pointed out. This characteristic is in conformity with the maximum value of the radiation spectrum of the solar cell and the sun.

As stated above, the inorganic phosphor 61 in the solar cell 1 according to the present invention has the aforesaid advantages. The solar cell 1 of the present invention is characterized by its spectrum converter 6 that can be made in the form of a film having a single layer or multi-layer structure. The film has filled therein an inorganic phosphor 61 in which the particles are spaced from one another at a distance about 20 times of the average diameter of the particle size, assuring film transmittance 80˜88% and light scattering 4˜6%.

The architecture of the solar cell 1 of the present invention has the following characteristics. At first, the spectrum converter 6 is made in the form of a polymeric covering. If a single flat plate is used during heat treatment and solar cell installation, the phosphor 61 distributed in the flat plate will crack and its transmittance will be lowered. The use of two or three primitive layers eliminates this drawback and maintains the high transmittance of the spectrum converter.

The second characteristic of the use of the polymeric flat plate is that: the inorganic phosphor 61 is preferably distributed in the center area of the flat plate, and the distance between the surface of the flat plate and the phosphor therein is h=10 d_{cp}, the average diameter of the particles of the phosphor 61 is d_{cp}=8˜10 μm, the pitch among the particles is h=80˜100 μm. Therefore, the concentration in one flat plate is δ=2h+d_{cp}≈165˜25 nm. The multi-element architecture of the solar cell adopts thermosetting to have the stacked flat plate architecture achieve excellent uniformity in converting radiation into light.

These advantages are seen in the solar cell 1 of the invention. In the solar cell 1 composition, the volume concentration of the inorganic phosphor 61 in the multi-layer spectrum converter 6 is 0.005˜0.025, and the quantum efficiency is 0.8˜0.95 when activated by short-wave. The aforesaid concentration of the inorganic phosphor 61 assures the proposed characteristics of the spectrum converter 6, including distribution uniformity in the volume of the polymeric flat plates, high transmittance of every flat plate and high luminescence of the whole assembly.

In the following Table III, it introduces the parameter measurement records on single-chip solar cells produced by “Suntech”.

TABLE III

| | Sample 1 | Sample 2 |
|---|---|---|
| Short-short current(A) | 4.74 | 5.735 |
| Open circuit voltage(V) | 0.613 | 0.704 |
| Power(W) | 2.12 | 2.60 |
| Efficiency(%) | 14.3 | 17.3 |

As indicated, the other device parameters of the solar cell are increased by 21˜25%. Therefore, increase of all parameters during working is the characteristic of the disclosed alternate form of the solar cell with a spectrum converter.

The invention also provides a spectrum converter 6 for use in a solar cell 1, which has filled therein an inorganic phosphor 61. The inorganic phosphor 61 absorbs radiation in purple, blue and green spectrum area, and emits light in yellow, orange-yellow and infrared area in the electromagnetic spectrum, enhancing the efficiency of the solar cell.

Further, the spectrum converter 6 is composed of an ethyl acetoacetate polymer film.

Further, the spectrum converter 6 radiates the absorbed short-wave light in the form of a multiband spectrum in which the half-wave width of one extreme surpasses 120 nm and is located on yellow-orange yellow spectrum area where the other extremes are distributed in the near infrared light 940˜1060 nm of half wave width 4˜6 nm that is in conformity with the maximum photosensitive area of the single chip silicon and within the Sun's radiation 900˜1100 nm.

Further, the inorganic phosphor 61 has the chemical composition of Y_{3-x-y-z-p}GdₓCe_{y}LuₚNd_{z}Al₅O₁₂, in which x=0.001˜0.30, y=0.001˜0.1, z=0.0005˜0.05, p=0.0005˜0.1 and, under this condition, the active ion Ce⁺³ is within the local radiation λ=510˜720 nm and the active ion Nd⁺³ is within the local radiation λ=920˜1100 nm.

Further, the spectrum converter 6 exists in the form of a thin film, having filled therein fine inorganic phosphor 61, and the particles of the inorganic phosphor 61 are spaced from one another at a distance about 20 times of the average diameter of the particle size, assuring film transmittance 80˜88% and light scattering 4˜6%.

Further, the inorganic phosphor 61 of the spectrum converter 6 has the volume concentration of 0.005˜0.025, and the light quantum efficiency of the inorganic phosphor 61 is 0.8˜0.95 when activated by a short-wave.

Further, the effective use of solar radiation by the spectrum converter 6 increases the total efficiency of the solar cell by 20%.

With respect to the composition of the ethyl acetoacetate polymer film, it is same as the aforesaid description.

In conclusion, the invention provides a solar cell 1 with a spectrum converter 6, having numerous advantages: 1. It eliminates the known drawbacks of conventional solar cells 1 having a light conversion glass layer; 2. It substantially increases the electric parameters of single crystal silicon-based solar cell 1 as well solar cell set; 3. It raises the solar cells 1 total efficiency by about 10˜20% and has this parameter in industrial samples reach 17˜19%; 4. It reduces the cost of the spectrum converter 6, thereby reducing the cost of the solar cell 1; and 5. It achieves production stability of single crystal silicon-based solar cell and solar cell set. Therefore, the invention effectively eliminates the drawbacks of prior art solar cell designs.

Although particular embodiments of the invention have been described in detail for purposes of illustration, various modifications and enhancements may be made without departing from the spirit and scope of the invention.

What is claimed is:

1. A solar cell comprising a single crystal silicon chip, an electrode system, and a glass plate covering said single crystal silicon chip, wherein the solar cell further comprises a spectrum converter set between said single crystal silicon chip and said glass plate, said spectrum converter having contained therein an inorganic phosphor to enhance the efficiency of the solar cell, said inorganic phosphor absorbing radiation in purple, blue and green light of the Sun's solar radiation and converting the absorption into a photoluminescent light in yellow, orange-yellow and infrared area in the electromagnetic spectrum.

2. The solar cell as claimed in claim 1, wherein said glass plate is a silicate glass plate.

3. The solar cell as claimed in claim 1, wherein said spectrum converter is composed of an ethyl acetoacetate polymer film.

4. The solar cell as claimed in claim 1, further comprising a polymer film sandwiched between said single crystal silicon chip and said spectrum converter.

5. The solar cell as claimed in claim 1, wherein said spectrum converter radiates the absorbed short-wave light in the form of a multiband spectrum in which the half-wave width of one extreme surpasses 120 nm and is located on yellow-orange yellow spectrum area where the other extremes are distributed in the near infrared light 940˜1060 nm of half wave width 4˜6 nm that is in conformity with the maximum photosensitive area of the single chip silicon and within the Sun's radiation 900˜1100 nm.

6. The solar cell as claimed in claim 1, wherein said inorganic phosphor has the chemical composition of Y_{3-x-y-z-p}GdₓCe_{y}LuₚNd₅Al₅O₁₂, in which x=0.001˜0.30, y=0.001˜0.1, z=0.0005˜0.05, p=0.0005˜0.1 and, under this condition, the active ion Ce⁺³ is within the local radiation λ=510˜720 nm and the active ion Nd⁺³ is within the local radiation λ=920˜1100 nm.

7. The solar cell as claimed in claim 1, wherein said spectrum converter is made in the form of a thin film, having filled therein said inorganic phosphor, and the particles of said inorganic phosphor are spaced from one another at a distance about 20 times of the average diameter of the particle size, assuring film transmittance 80˜88% and light scattering 4˜6%.

8. The solar cell as claimed in claim 1, wherein said inorganic phosphor of said spectrum converter has the volume concentration of 0.005˜0.025, and the light quantum efficiency of said inorganic phosphor is 0.8˜0.95 when activated by a short-wave.

9. The solar cell as claimed in claim 1, wherein the effective use of solar radiation by said spectrum converter increases the total efficiency of the solar cell by 20%.

10. The solar cell as claimed in claim 4, wherein said polymer film is prepared from ethyl acetoacetate.

11. A spectrum converter for use in a solar cell, said spectrum converter having contained therein an inorganic phosphor to enhance the efficiency of the solar cell, said inorganic phosphor absorbing radiation in purple, blue and green light of the Sun's solar radiation and converting the absorption into a photoluminescent light in yellow, orange-yellow and infrared area in the electromagnetic spectrum.

12. The spectrum converter as claimed in claim 11, which is composed of a polymer film.

13. The spectrum converter as claimed in claim 11, which radiates the absorbed short-wave light in the form of a multiband spectrum in which the half-wave width of one extreme surpasses 120 nm and is located on yellow-orange yellow spectrum area where the other extremes are distributed in the near infrared light 940˜1060 nm of half wave width 4˜6 nm that is in conformity with the maximum photosensitive area of the single chip silicon and within the Sun's radiation 900˜1100 nm.

14. The spectrum converter as claimed in claim 11, wherein said inorganic phosphor has the chemical composition of Y_{3-x-y-z-p}GdₓCe_{y}LuₚNd_{z}Al₅O₁₂, in which x=0.001˜0.30, y=0.001˜0.1, z=0.0005˜0.05, p=0.0005˜0.1 and, under this condition, the active ion Ce⁺³ is within the local radiation λ=510˜720 nm and the active ion Nd⁺³ is within the local radiation λ=920˜1100 nm.

15. The spectrum converter as claimed in claim 11, which is made in the form of a thin film, having filled therein said inorganic phosphor, and the particles of said inorganic phosphor are spaced from one another at a distance about 20 times of the average diameter of the particle size, assuring film transmittance 80˜88% and light scattering 4˜6%.

16. The spectrum converter as claimed in claim 11, wherein said inorganic phosphor of said spectrum converter has the volume concentration of 0.005˜0.025, and the light quantum efficiency of said inorganic phosphor is 0.8˜0.95 when activated by a short-wave.

17. The spectrum converter as claimed in claim 11, wherein the effective use of solar radiation by the spectrum converter increases the total efficiency of the solar cell by 20%.

18. The spectrum converter as claimed in claim 12, wherein said polymer film is composed of ethyl acetoacetate.
